(19) United States
(12) Patent Application Publication
(10) Pub. No.: US 2006/0051680 A1
(43) Pub. Date: Mar. 9, 2006

(54) Combining image imbalance compensation and optical proximity correction in designing phase shift masks

(76) Inventors: Alexander V. Tritchkov, Hillsboro, OR (US); Seongtae Jeong, Portland, OR (US)

Correspondence Address: FISH & RICHARDSON, PC, P.O. BOX 1022, MINNEAPOLIS, MN, 55440-1022, US

(21) Appl. No.: 10/933,948

(22) Filed: Sep. 3, 2004

(51) Int. Cl. G06F 17/50; G03F 1/00

(52) U.S. Cl. 430/5; 716/19; 716/21

(57) ABSTRACT

This application includes techniques for applying image imbalance compensation by aperture sizing and optical proximity approximation in designing a phase mask.

All rights in connection with this application are assigned to Intel Corporation.

This application relates to phase shifting masks used in photolithography.

A phase mask used in photolithography is a template imprinted with a desired spatial pattern for microstructures, integrated circuits, or a combination of one or more microstructures and one or more integrated circuits. Such a phase mask may have transmissive regions with pre-assigned relative phase shifts within the pattern. In operation, the phase mask is illuminated with radiation and the transmission of the radiation through the phase mask is imaged by a lens imaging system onto a photoresist layer on a substrate. This exposure of the photoresist layer and the subsequent patterning process transfer the pattern in the phase mask to the photoresist layer. The phase mask may be an alternating phase shift mask (APSM) that has adjacent transmissive regions or apertures with a relative phase shift of 180 degrees. Light fields from two adjacent transmissive apertures interact when they overlay to produce destructive interference in the imaging process and thus produce sharp images of the features in the phase mask. In comparison with amplitude masks with opaque and transmissive features without the relative phase shifts, phase masks can improve the image resolution and reduce the critical dimension (CD) of the patterned photoresist.

### BRIEF DESCRIPTION OF THE DRAWINGS

FIG. 1 shows an example of the chrome undercut in phase apertures for compensation of image imbalance between 180-degree phase apertures and O-degree phase apertures.

FIG. 2 shows an exemplary design flow for designing a phase mask.

FIGS. 3A through 3E show shapes of an exemplary phase mask at various stages of the design flow shown in FIG. 2.

FIGS. 4A and 4B show shapes of the exemplary phase mask in FIG. 3E in additional verification steps performed subsequent to the design flow in FIG. 2.

### DETAILED DESCRIPTION

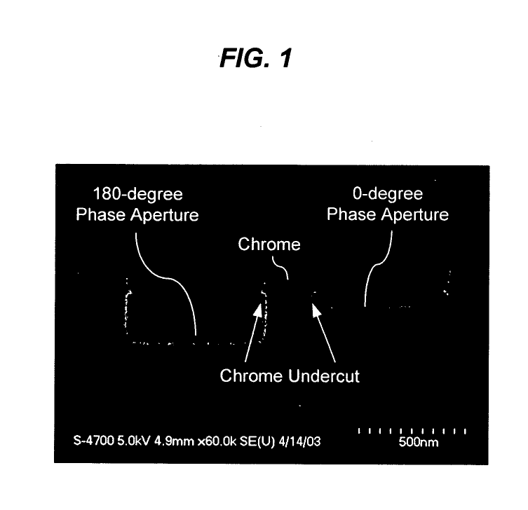

This application describes, among others, techniques for combining imaging imbalance compensation and optical proximity correction (OPC) in designing a phase mask prior to manufacturing of the phase mask to reduce distortions in the final image projected on the photoresist layer when such a phase mask is used in photolithography. Image imbalance may be represented by the difference between intensities of images from different transmissive phase apertures on the phase mask with different phase delays. The phase apertures may be in various shapes such as polygons. An alternating phase shift mask, for example, may have phase apertures with relative phase values of 0 degree and 180 degrees. A trench for a 180-degree phase aperture is deeper than a trench for a 0-degree phase aperture. The scattering from the side walls of the trenches 15 can make the intensity of light from a 180-degree phase aperture less than that from a 0-degree phase aperture. As a result, this image imbalance can alter desired patterns imaged onto the photoresist. For example, the image of the 180 degree aperture can become smaller than the image of the 0 degree aperture and the position of the line edge formed on the wafer may be shifted due to the image imbalance. One way to correct the adverse image imbalance in phase masks is to create a chrome undercut in forming phase apertures by etching during the mask manufacturing process. FIG. 1 illustrates an example of the chrome undercut.

One feature of the present techniques is to incorporate the image imbalance compensation into the optical proximity correction (OPC) in designing a phase mask. Hence, the capability of the image imbalance compensation is built into the design of the phase apertures. The image imbalance can be partially or entirely compensated by simply using this specially designed phase mask in the photolithographic process.

As an example, the phase mask with built-in compensation for image imbalance may be designed as follows. The phase apertures for a phase mask may be first designed according to a structure pattern to be formed a photoresist layer in a photolithography process that uses the phase mask. Next, the sizes of the phase apertures are reduced. Optical proximity correction is then applied to the phase apertures in reduced sizes. After the optical proximity correction (OPC), the sizes of the phase apertures are increased. Two adjacent phase apertures in the above design example may have phase values that are shifted by 180 degrees and may be reduced in size in the above size-reducing step by different amounts.

This application of the image imbalance compensation in the design stage of a phase mask has a number of advantages. For example, the techniques can be applied to smaller CD patterning and hence are scalable. The compensation for the image imbalance during the design stage may allow for elimination of the chrome undercut for compensating the image imbalance during manufacturing of the phase mask and thus simplifies the mask manufacturing process. The compensation for image imbalance during the design stage of a phase mask may also be combined with the chrome undercut formed during the manufacturing stage to compensate for image imbalance in both the design and manufacturing of the phase mask. As yet another example, the present techniques include the effect of the image imbalance and its compensation in the mask design modeling to improve the capacity of the mask design modeling so that optical proximity correction algorithms can be designed to be more accurate and faster than other algorithms without such built-in compensation for the image imbalance.

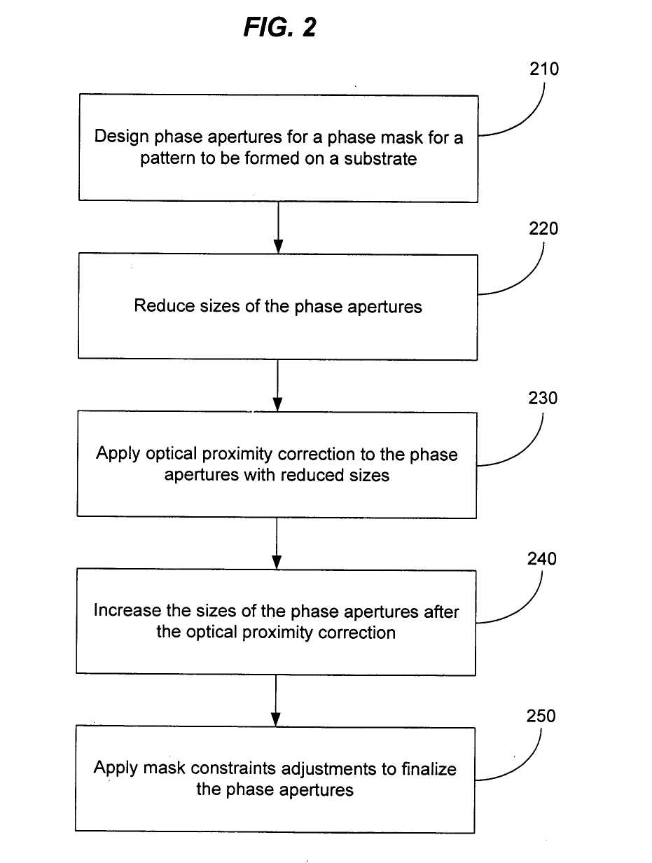

FIG. 2 illustrates one example of a design flow in designing a phase mask with the above compensation for the image imbalance. The steps in the design flow, either in part or entirely, may be implemented as computer software design functions or routines that are stored on one or more computer storage media or devices and are executed by one or more computer processors. At step 210, initial designs of phase apertures for a pattern to be formed on a substrate are generated. This may be achieved by using a suitable phase aperture design software tool. In the generated pre-OPC phase apertures, the target Cr CD is set to a desired value. At step 220, the sizes of the initial phase apertures are reduced. A rule-based algorithm may be applied to reduce the sizes where a set of predetermined rules are used in resizing. The 0-degree and 180-degree phase apertures may be reduced in size by different amounts. The different amounts of sizing for the 0-degree and 180-degree phase polygons may be determined from the wafer data. In this regard, the wafer data may be used to determine the total sizing differential between the 0-degree and 180-degree phase polygons and then the model fit may be used to determine amounts of sizing common to 0-degree and 180-degree phase regions. Upon completion of the size reduction, the optical proximity correction is started from a different target (larger Cr CD than desired). At step 230, optical proximity correction is applied to the reduced phase apertures. As an example, the shape and dimension of one or more edges of a phase aperture may be changed to compensate for certain undesired effects of the photolithography process. A pre-selected model may be used to simulate the final pattern formed on the substrate from the given phase apertures and to control the optical proximity correction.

After the optical proximity correction, the sizes of the modified phase apertures are enlarged at step 240. The sizes of the phase apertures after the optical proximity correction may be increased by the same amount as the amount of reduction of the phase apertures prior to the optical proximity correction. The sizing operations in steps 220 and 240 are used to compensate for the image imbalance and may depend on certain properties of the phase mask, such as the etch depth and presence of the chrome undercut. Aperture resizing may adversely affect certain mask constraints due to the photolithography process.

The optical proximity correction applied in step 220 performs edge adjustments to compensate for the proximity effects based on the targeting done in step 210. Due to the down sizing in step 220, the OPC process starts from a different target (usually larger Cr CD than desired), the step 240 increases sizes of the phase regions by the same amounts used at step 220 for phase apertures, respectively, so that when the phase mask is used to project a pattern onto the photoresist in the fabrication, the final image on the wafer comes at the desired wafer image CD which is the desired Cr CD generated in step 210. Therefore, the upsizing in step 240 does not undo the downsizing in step 220 and is an integral part of the image imbalance compensation implemented in the design of the phase mask.

To preserve the mask constraints, the phase apertures after the step 240 are adjusted at step 250 based on the required mask constraints. This step essentially finalizes the design of the phase apertures and the finalized phase mask design is now ready for use in manufacturing the actual phase masks.

In the above design flow, image imbalance is compensated through simultaneous aperture sizing at steps 220 and 240 and the proximity effect correction at step 220. Additional checking steps may be further added after the step 250 to examine the finalized phase mask design. In one implementation, for example, the finalized phase apertures may be reduced in size to produce reduced phase apertures by the same amounts used in steps 220 and 240 in FIG. 2. Next, a model-based lithography rule is applied to the apertures to verify the finalized apertures produced at the step 250 in FIG. 2.

The design data at the end of step 250 is ready for making the phase mask. The additional two checking steps are only for lithography verification of the completed phase mask design and are not part of the design process. However, these verification steps can be important to ensure the quality of the OPC process.

In applying the above design flow, the thick mask effect, which is accountable for image imbalance, may be simulated through a thin mask formalism using the phase aperture sizing method. The sizing depends on the properties of the mask, such as etch depth, the presence of the chrome undercut, and the combination of these and other effects. The validity of this modeling approach may be verified by comparing AIMS (Aerial Image Measurement System) data to simulation as well as comparison between the wafer print data and simulation. Software algorithms are used to accommodate the above modeling approach. Rules-based aperture sizing and model-based proximity effects correction are applied to each of the 180-degree phase and 0-degree phase apertures through a combination of simultaneous targeting model evaluations/edge adjustments and Boolean operations. Image imbalance compensation through aperture sizing could have negative impact on CD control and mask manufacturing capability without effective mask constraints preservation. Preservation of mask constraints is achieved through rules-based edge-to-edge and corner-to-corner adjustments of the 0-degree and 180-degree polygon apertures.

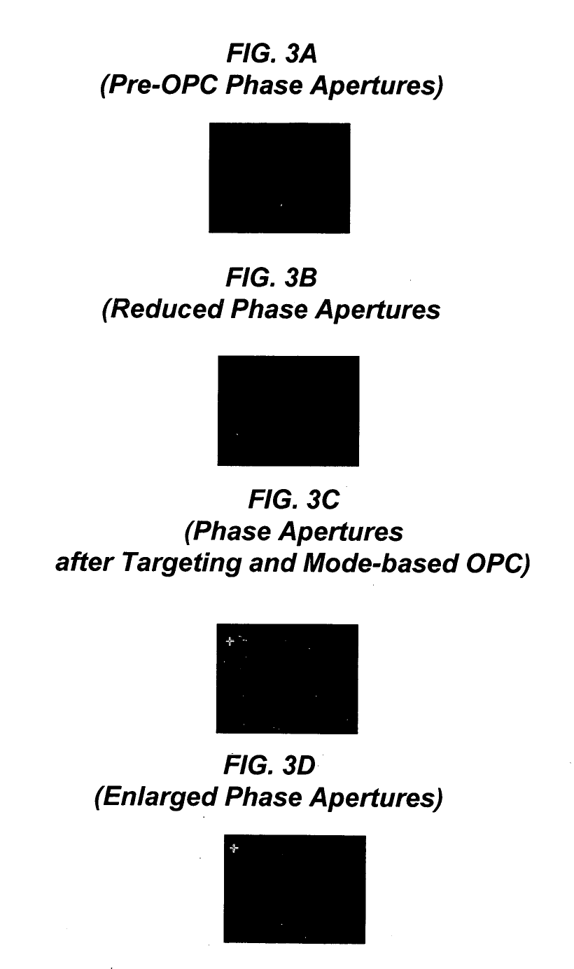

FIGS. 3A through 3E show examples of patterns of two phase apertures of a APSM phase mask in the design flow in FIG. 2 for image imbalance compensation through simultaneous phase aperture sizing and optical proximity correction. In FIG. 3A, two rectangular phase apertures are designed after the step 210 in FIG. 2 for the phase mask where the upper aperture has a relative phase shift of 0 and the lower aperture has a relative phase shift of 180 degrees. The alternating 0-degree phase polygons and 180-degree phase polygons are synthesized to alternate across each line of the critical dimension to be printed on a wafer using the phase mask. Each line of the critical dimension has a 0-degree phase polygon (indicated in purple) assigned on one side, and an opposite phase 180-degree phase polygon (indicated in red) assigned on the other side of the line.

FIG. 3B shows the reduced phase apertures after the sizing operation in step 220 in FIG. 2. In this particular example, the 0-degree phase polygon is reduced by a first amount of a few nanometers and the 180-degree phase polygon is reduced by a different, second amount, usually over 10 nm. Hence, each phase polygon becomes smaller while the spacing between adjacent polygons has become larger by the total amount of reduction in both kinds of phase polygons. The amounts of down sizing in the phase polygons are determined from the experimental data during the model calibration and depend on, among other factors, the amount of the chrome undercut etch applied during the mask manufacturing on the test mask that is used to collect the data for the model calibration. In this particular example, a test mask with no undercut etch based on a conventional design without using the simultaneous resizing and OPC in the design was used so that the images of the two phase apertures are imbalanced relative to each other, i.e., image imbalance is not compensated through mask manufacturing. Based on this test mask, the total down sizing was determined in order to compensate for the image imbalance.

FIG. 3C shows the phase apertures after the optical proximity correction at step 220. In this process the model-based OPC and the targeting are applied simultaneously to the phase apertures. The targeting is done by adjusting the evaluation points of the model appropriately for the desired linewidth and adjusting the edges of the phase polygons iteratively according to the model.

FIG. 3D shows the phase apertures after the second sizing in the step 240 in FIG. 2. In this example, the 0-degree phase polygons are sized up by the same amount used in reducing the size of the 0-degree phase polygons in FIG. 3B. The 180-degree phase polygons are sized up by the same amount used in reducing the size of the 180-degree phase polygons in FIG. 3B. As a result, the phase polygons become larger while the space between two adjacent opposite-phase polygons is decreased.

FIG. 3E shows the finalized phase apertures after the mask constraint adjustments in the step 250. The process of mask manufacturing has certain limitations, called mask constraints. The adjustments for mask constraints are applied in the phase mask design to ensure that the final phase mask design is compliant with requirements for mask manufacturing. For example, one critical mask constraint is due to the amount of remaining chrome between a 0-degree phase aperture and an adjacent 180-degree phase aperture after the OPC and the subsequent sizing-up operation. In this particular example, the minimum Chrome width between any two segments of the phase mask that was allowed to ensure robust mask manufacturing was 40 nm along the direction perpendicular to the edge direction and a chrome width of 55 nm was allowed between corners (corner-to-corner) and between corners and segments, in all angles between 0 and 180 degrees. The preservation of the minimum Chrome mask constraints is achieved through rule-based edge-to-edge, corner-to-corner and corner-to-edge adjustments of the 0-degree and 180-degree phase polygons. These adjustments may be done in several stages to ensure a gradual transition between segments generated during this process and to guarantee the rule-based adjustments do not significantly affect the control of the critical dimension in the printed image on the wafer.

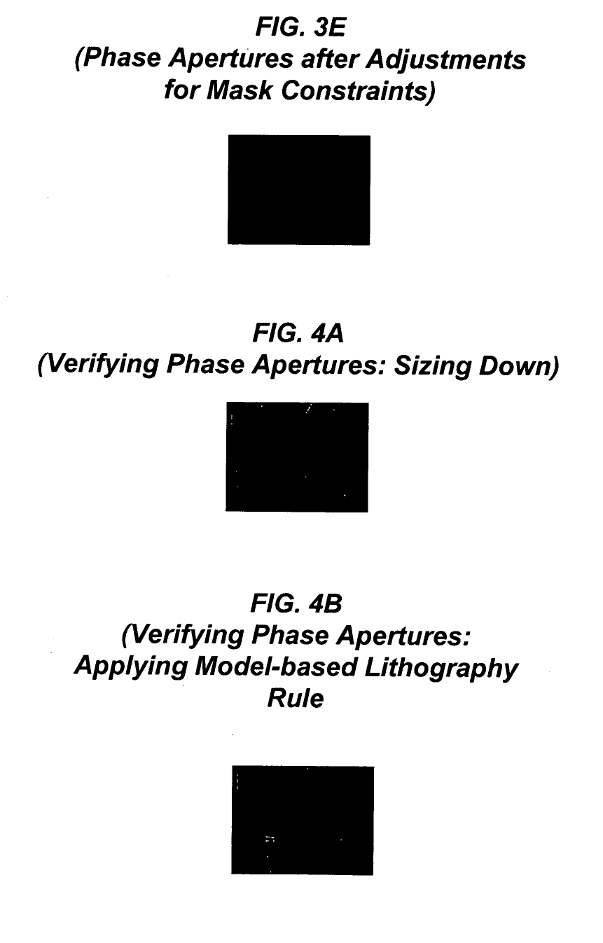

FIGS. 4A and 4B further illustrate the upper and lower phase apertures in the above example during subsequent verification steps. In FIG. 4A, each of the phase apertures in FIG. 3E is reduced in size by the same amount that it is increased in FIG. 3B. Next as shown in FIG. 4B, the apertures are checked by using a model-based lithography rule. The above additional two steps are for the lithography verification purpose. The sizing down step in FIG. 4A is used to recover the sizes of the 0-degree and 180-degree phase polygons (the Cr width between them), respectively, to the value which the model is applied to them during the OPC. Next, the lithography images are simulated on the phase mask using the OPC model to verify the desired linewidth of (1× wafer) with the adequate CD control.

The flow in FIG. 2 can be used to tapeout a mask set of a chip. The phase mask designed in the example shown in FIGS. 3A-3E was used for tapeout of an SRAM test chip. The mask set was manufactured successfully and the wafers were exposed in the fabrication to verify this approach of image imbalance compensation. The mask qualification was completed successfully. Image imbalance compensation was measured with silicon wafers, and confirmed to meet the specification for the compensation. This approach may be used for the next generation lithography processes based on APSM.

The above operations in the exemplary design flow may be written as computer instructions or routines stored on a machine-readable medium such as a computer storage device. The storage device may be, for example, an optical disk, a magnetic disk, a memory IC chip, or other storage devices. The instructions are executable to cause the a machine such as a computer or other information device to carry out the desired operations for designing a phase mask. The pattern of the finalized phase mask design may be converted into mask data in a binary data exchange format such as a GDS format (e.g., GDSII). The mask data is sent to a mask fabrication facility and is read into a computer-controlled mask fabrication machine or system. The system then makes a physical pattern on a mask substrate according to the mask data. The mask data generated by the mask designer may be stored on a storage medium such as a portable storage device and the storage medium is sent to the mask fabrication facility. Alternatively, the mask data may be stored on a networked storage device connected to a communication network and is then fetched from the storage device and transferred to the mask fabrication facility via the communication network.

The above compensation of the image imbalance implemented in the design of a phase mask may completely eliminate the need for the chrome undercut during the fabrication of the phase mask so that the phase mask is made without the chrome undercut and the actual image imbalance in the photolithography process using such a phase mask is small and within an acceptable tolerance level. Alternatively, a phase mask may be designed to utilize the chrome undercut during the mask fabrication to compensate for the image imbalance. Such a phase mask may still be designed to include the above compensation for the image imbalance by resizing and OPC to further compensate for any residual image imbalance that is not completely compensated by the chrome undercut. In this design, for a given chrome undercut, the typical residual image imbalance may be measured from testing phase masks. This information of the typical residual image imbalance is then used to configure the resizing and the OPC during the design of the phase mask to effectuate the finalized phase apertures that can compensate for the typical residual image imbalance.

Only a few implementations are described. However, it is understood that variations and enhancements may be made.

What is claimed is:

1. A method, comprising:
designing phase apertures for a phase mask according to a structure pattern to be formed on a photoresist layer in a photolithography process that uses the phase mask;
reducing size of each phase aperture;
applying optical proximity correction to the phase apertures with reduced sizes; and
increasing size of each phase aperture after the optical proximity correction to finalize design of the phase apertures.

2. The method as in claim 1, further comprising subsequently applying adjustments to the phase apertures to preserve mask constraints of manufacturing to finalize the phase apertures.

3. The method as in claim 2, further comprising verifying the finalized phase apertures by first reducing sizes of the finalized phase apertures and then applying a lithography rule to verify the finalized phase apertures with reduced sizes.

4. The method as in claim 2, further comprising causing the phase mask to be manufactured without a chrome undercut.

5. The method as in claim 2, further comprising causing the phase mask to be manufactured with a chrome undercut to compensate for an image imbalance between phase apertures with different phase values, and wherein the reducing the sizes of the phase apertures, applying the optical proximity correction, and increasing the sizes of the phase apertures are designed to compensate for a residue image imbalance that is not compensated by the chrome undercut.

6. The method as in claim 1, wherein each phase aperture after the optical proximity correction is increased by an amount that the phase aperture is reduced in size prior to the optical proximity correction.

7. The method as in claim 1, further comprising applying a set of predetermined rules in reducing and increasing sizes of the phase apertures.

8. The method as in claim 1, further comprising applying the optical proximity correction according to a simulation based on a model.

9. The method as in claim 1, wherein two adjacent phase apertures have phase values that are shifted by 180 degrees and are reduced in size by different amounts in reducing the size of each phase aperture.

10. The method as claim 9, wherein the size of a phase aperture that has a phase value greater than an adjacent phase aperture is reduced in size more than the adjacent phase aperture in reducing the size of each phase aperture.

11. A method, comprising:
designing phase apertures in a phase mask with relative phase values of zero and 180 degrees for use in a photolithography process; and
applying image imbalance compensation and optical proximity correction to the phase apertures by sequentially (1) reducing size of each phase aperture; (2) applying optical proximity correction to the reduced phase apertures; and (3) enlarging size of each phase aperture.

12. The method as in claim 11, further comprising subsequently verifying the phase apertures by first reducing sizes of the phase apertures and then applying a lithography rule to verify the phase apertures with reduced sizes.

13. The method as in claim 11, further comprising applying the optical proximity correction according to a simulation based on a model.

14. The method as in claim 11, wherein two adjacent phase apertures have phase values that are shifted by 180 degrees and are reduced in size by different amounts.

15. The method as claim 14, wherein the size of a phase aperture that has a phase value greater than an adjacent phase aperture is reduced in size more than the adjacent phase aperture.

16. An article comprising at least one machine-readable storage medium that stores machine-executable instructions, the instructions causing a machine to:
design phase apertures in a phase mask according to a structure pattern to be formed on a photoresist layer in a photolithography process;
reduce sizes of the phase apertures;
apply optical proximity correction to the phase apertures with reduced sizes;
increase sizes of the phase apertures after the optical proximity correction; and
subsequently apply adjustments to the phase apertures to preserve mask constraints of manufacturing to finalize the phase apertures.

17. The article as in claim 16, wherein the instructions further cause the machine to verify the finalized phase is apertures.

18. The article as in claim 17, wherein the verification comprises reducing sizes of the finalized phase apertures and applying a lithography rule to check the finalized phase apertures with reduced sizes.

19. The article as in claim 16, wherein the instructions further cause the machine to apply a simulation based on a model in the optical proximity correction.

20. The article as in claim 16, wherein two adjacent phase apertures have phase values that are shifted by 180 degrees, and the instructions further cause the machine to reduce sizes of the two adjacent phase apertures by different amounts in reducing sizes of the phase apertures.

21. The article as in claim 20, wherein the instructions further cause the size of a phase aperture that has a phase value greater than an adjacent phase aperture to be reduced more than the adjacent phase aperture in reducing sizes of the phase apertures.

22. An article comprising at least one machine-readable storage medium that stores machine-executable phase mask data generated by a phase mask design process which comprises:
designing phase apertures for a phase mask according to a structure pattern to be formed on a photoresist layer in a photolithography process;
reducing size of each phase aperture;
applying optical proximity correction to the phase apertures with reduced sizes;
increasing size of each phase aperture after the optical proximity correction;
subsequently applying adjustments to the phase apertures to preserve mask constraints of manufacturing to finalize the phase apertures; and
converting the finalized phase apertures for the phase mask into the phase mask data, wherein the mask data is readable and executable by a mask fabrication machine to form the finalized phase apertures on a mask substrate.

23. The article as in claim 22, wherein the mask data is in a binary data exchange format.

24. The article as in claim 22, wherein the mask data is in a GDS format.
